(19) United States
(12) Patent Application Publication
(10) Pub. No.: US 2026/0293317 A1
(43) Pub. Date: Sep. 24, 2026

(54) MODULAR 3D LNA INTEGRATED CIRCUIT

(71) Applicant: Murata Manufacturing Co., Ltd., Nagaokakyo-Shi, Kyoto (JP)

(72) Inventors: Sinan GOKTEPELI, SAN DIEGO, CA (US); Emre AYRANCI, SAN DIEGO, CA (US); Miles SANNER, SAN DIEGO, CA (US); Dheeraj MOHATA, SAN DIEGO, CA (US); Kouassi Sebastien KOUASSI, SAN DIEGO, CA (US)

(21) Appl. No.: 19/473,570

(22) PCT Filed: Mar. 29, 2024
(86) PCT No.: PCT/US2024/022243

§ 371 Date: Oct. 8, 2025

Related U.S. Application Data
(63) Continuation-in-part of application No. PCT/US2023/017960, filed on Apr. 7, 2023.
(60) Provisional application No. 63/330,610, filed on Apr. 13, 2022.
(60) Provisional application No. 63/495,499, filed on Apr. 11, 2023.

(51) Int. Cl. H10D 88/00; H03F 3/24

(52) U.S. Cl. CPC H10D 88/00; H03F 3/245; H10D 88/01; H03F 2200/451

(57) ABSTRACT

Improved integrated circuit configurations of field-effect transistors (FETs), particularly within a low-noise amplifier (LNA), that reduces unwanted parasitics. Embodiments take advantage of the characteristics of a stacked-pair of ICs in a 3-dimensional (3D) configuration to beneficially assign FETs of various LNA circuit designs to different ones of the paired ICs within the 3D stack. Advantages include optimizing the performance of the circuitry within each IC in the 3D stack and reducing parasitics by shortening routing distances between circuit elements and reducing conductor overlaps within each IC of the 3D stack. One embodiment comprises a 3-dimensional IC including a first IC including a first transistor component of an amplifier, and a second IC including a second transistor component of the amplifier, wherein the first IC is bonded to the second IC such that the first transistor component of the amplifier is electrically coupled to the second transistor component of the amplifier.

### CROSS-REFERENCE TO RELATED APPLICATIONS

The present application claims priority to U.S. Provisional Application No. 63/495,499 filed on Apr. 11, 2023, entitled “Modular 3D LNA Integrated Circuit”, the contents of which are incorporated herein by reference in their entirety. The present application is also a continuation-in-part application of PCT Application No. PCT/US2023/017960, filed on Apr. 7, 2023, entitled “3-Dimensional Integrated Circuit Structures and Circuits”, which in turn claims priority to U.S. Patent Application Ser. No. 63/330,610, filed Apr. 13, 2022, entitled “3-Dimensional Integrated Circuit Structures and Circuits”, the contents of all of which are incorporated herein by reference in their entireties.

### FIELD

The invention relates to electronic integrated circuits, and more particularly to radio frequency amplifier integrated circuits.

### BACKGROUND

Many modern electronic systems include radio frequency (RF) receivers; examples include cellular telephones, personal computers, tablet computers, wireless network components, televisions, cable system “set top” boxes, and radar systems. Many RF receivers are paired with RF transmitters in the form of transceivers, which often are quite complex two-way radios. In some cases, RF transceivers are capable of transmitting and receiving across multiple frequencies in multiple bands.

Amplifiers are a common component in RF transmitters, receivers, and transceivers, and are frequently used for power amplification of transmitted RF signals and for low-noise amplification of received RF signals. For many RF systems, particularly those requiring low power and/or portability (e.g., cellular telephones, WiFi-connected computers, cameras, and other devices), it has become common to use silicon-on-insulator (SOI) field-effect transistors (FETs), and silicon-on-sapphire (SOS) FETs (SOS being a type of SOI fabrication technology). In addition, many other semiconductor technologies, including gallium nitride (GaN), may be used to fabricate FET devices.

FIG. 1 is a simplified schematic diagram of a generalized embodiment of a prior art low-noise amplifier (LNA) circuit 100. In the illustrated example, the LNA circuit 100 includes an amplifier block 102 comprising a stack of series-connected field-effect transistors (FETs) CS, CG in a cascode arrangement. An RF input signal applied to an RF input terminal RF_{IN} may be passed through an input impedance matching circuit 104 and coupled to the gate of a common-source lower FET CS. The source of lower FET CS is typically connected through a degeneration inductor L_{DEG} to a reference potential, such as circuit ground.

The source of a common-gate upper FET CG is connected to the drain of lower FET CS. The drain of upper FET CG provides an amplified RF output signal through a DC blocking capacitor C to an RF output terminal RF_{OUT}. Capacitor C may also aid in providing output impedance matching. A load inductor L_{LOAD} is connected between a source voltage V_{DD} and the drain of upper FET CG to aid in providing impedance matching and to provide a bias feed to the amplifier block 102. In the illustrated example, the RF output terminal RF_{OUT} is shown coupled to a typical load, represented as a resistor R_{L}. The value of R_{L} is typically 50 ohms for many modern RF circuits.

A bias circuit 106 is configured to provide a suitable bias voltage CG_V_{BIAS} to the common-gate upper FET CG and a suitable bias voltage CS_V_{BIAS} to the common-source lower FET CS, in known fashion. Additional well-known circuit elements that might be included in some applications (e.g., bypass capacitors, tuning circuits, and feedback circuits) are omitted for clarity.

Increases in the frequency of RF communications bands and channels, as well as a continuing increase in the number of bands and channels in use, has pushed current LNA architectures to their limits. A particular challenge—especially at frequencies above about 24 GHz—is parasitic capacitances, inductances, and/or resistances (collectively, “parasitics”) resulting from signal routing connectors in current solid-state integrated circuit (IC) designs. To better understand this challenge, it may be useful to consider how FETs are currently generally structured.

FIG. 2 is a cross-sectional diagram of a conventional monolithic SOI IC 200 that includes multiple FETs. In the illustrated example, a substrate 202 (e.g., sapphire, trap rich Si, or high resistivity Si) supports a substructure 204 comprising a buried oxide (BOX) insulator layer 206 which supports an active layer 208. In the illustrated example, two FET devices (within dashed ovals 209a, 209b) are formed in and on the active layer 208. Each FET includes a source S, drain D, and gate G. The gate G is spaced from the active layer 208 by a gate insulator 210. A superstructure 212 is formed on the active layer 208, and generally comprises inter-layer dielectric (ILD) with formed layers of conductive material (e.g., metallization layers M1, M2, M3, etc.), and vertical conductors (vias) 212 of various sizes. Portions of the upper-most metallization layer (M3 in this example) may be to bonding connected pads 214 by corresponding vias 212.

The FETs in FIG. 2 are highly simplified depictions. In practical ICs, the FETs may comprise numerous interdigitated source and drain “fingers” and a corresponding set of interposed gates to accommodate a specified current level. In conventional 2-dimensional (2D) IC layouts, connecting metallization layers overlap, which can lead to unwanted parasitics.

For example, FIG. 3A is a top-down plan view of a pair of FETs CG and CS (corresponding to the CG and CS FETs in FIG. 1) in a first prior art 2D layout. FET CG includes a gate metallization layer 302a overlaying a corresponding active region 304a of a substrate, a drain metallization layer 306a having fingers in parallel with one or more portions of the gate metallization layer 302a, and a source metallization layer 308a having fingers in parallel with one or more portions of the gate metallization layer 302a. The portions of the gate metallization layer 302a between the fingers of the drain metallization layer 306a and the source metallization layer 308a define the conduction channel between the source and drain of the FET CG. Similarly, FET CS includes a gate metallization layer 302b overlaying a corresponding active region 304b of a substrate, a drain metallization layer 306b having fingers in parallel with one or more portions of the gate metallization layer 302b, and a source metallization layer 308b having fingers in parallel with one or more portions of the gate metallization layer 302b. The portions of the gate metallization layer 302b between the fingers of the drain metallization layer 306b and the source metallization layer 308b define the conduction channel between the source and drain of the FET CS. The FETs CG, CS are also shown as including a corresponding gate signal line 310a, 310 b, typically realized in a different metallization layer and coupled to the gate metallization layers 302a, 302b through one or more vias 312.

FIG. 3B is a top-down plan view of a pair of FETs CG and CS (corresponding to the CG and CS FETs in FIG. 1) in a second prior art 2D layout. Elements are referenced the same as in FIG. 3A. The drain metallization layers 306a, 306b and the source metallization layers 308a, 308b are linear vertical extents that are perpendicular to the horizontal members of the corresponding gate metallization layers 302a, 302b, connecting to the actual respective source and drain regions through conductive visas 314.

In both configurations shown in FIGS. 3A and 3B, the metallization layers overlap, which can lead to unwanted parasitics, particularly at very high RF frequencies (e.g., >24 GHZ).

Accordingly, there is a need for an improved configuration of FETs, particularly within an LNA, that reduces unwanted parasitics. The present invention addresses this need.

### SUMMARY

The present invention encompasses improved configurations of field-effect transistors (FETs), particularly within a low-noise amplifier (LNA), that reduces unwanted parasitic capacitances, inductances, and/or resistances (collectively, “parasitics”). Embodiments of the present invention take advantage of the characteristics of a stacked-pair of ICs in a 3-dimensional (3D) configuration to beneficially assign FETs of various LNA circuit designs to different ones of the paired ICs within the 3D stack. Advantages include optimizing the performance of the circuitry within each IC in the 3D stack and reducing parasitics by shortening routing distances between circuit elements within each IC of the 3D stack and reducing conductor overlaps.

A first embodiment includes a 3-dimensional integrated circuit including a first integrated circuit including a first transistor component of an amplifier, and a second integrated circuit including a second transistor component of the amplifier, wherein the first integrated circuit is bonded to the second integrated circuit such that the first transistor component of the amplifier is electrically coupled to the second transistor component of the amplifier.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1 is a simplified schematic diagram of a generalized embodiment of a prior art low-noise amplifier (LNA) circuit.

FIG. 2 is a cross-sectional diagram of a conventional monolithic SOI IC that includes multiple FETs.

FIG. 3A is a top-down plan view of a pair of FETs CG and CS (corresponding to the CG and CS FETs in FIG. 1) in a first prior art 2D layout.

FIG. 3B is a top-down plan view of a pair of FETs CG and CS (corresponding to the CG and CS FETs in FIG. 1) in a second prior art 2D layout.

FIG. 4A is a cross-sectional view of two ICs in the process of being bonded together into a 3D IC stack.

FIG. 4B is a cross-sectional view of the two ICs of FIG. 4A after being bonded together into a 3D IC stack.

FIG. 4C is a cross-sectional view of a variant configuration of the two ICs of FIG. 4A after being bonded together into a 3D IC stack.

FIG. 5 is a cross-sectional view of a portion of a 3D IC stack showing a first embodiment of an LNA circuit configuration.

FIG. 6A is a cross-sectional view of a portion of a 3D IC stack showing a second embodiment of an LNA circuit configuration.

FIG. 6B is a top-down plan view of an example layout for a CS FET (corresponding to the CS FET in FIG. 6A) within a top IC.

FIG. 6C is a top-down plan view of an example layout for a CG FET (corresponding to the CG FET in FIG. 6A) within a bottom IC.

FIG. 7 is a cross-sectional view of a portion of a 3D IC stack showing an embodiment of a dual-LNA circuit configuration.

FIG. 8 is a cross-sectional view of a portion of a 3D IC stack showing a first embodiment of an LNA circuit configuration that includes integrated inductance elements.

FIG. 9A is a cross-sectional view of a portion of a 3D IC stack showing a second embodiment of an LNA circuit configuration that includes integrated inductance elements.

FIG. 9B is a bottom-up plan view of a pair of FETs CG and CS (corresponding to the CG FET and the CS FET in FIG. 9A) in a first 2D layout within a top IC.

FIG. 9C is a bottom-up plan view of a FET (which may correspond to either of the CG FET or the CS FET in FIG. 9A) in a second 2D layout within a top IC.

FIG. 9D is a bottom-up plan view of a FET (which may correspond to either of the CG FET or the CS FET in FIG. 9A) in a third 2D layout within a top IC.

FIG. 10 is a cross-sectional view of a portion of a 3D IC stack showing a third embodiment of an LNA circuit configuration that includes integrated inductance elements.

FIG. 11 is a cross-sectional view of a portion of a 3D IC stack showing a fourth embodiment of an LNA circuit configuration that includes inductance elements.

FIG. 12 is a perspective view of a helical inductor fabricated as part of a 3D IC stack.

FIG. 13 is a top plan view of a substrate that may be, for example, a printed circuit board or chip module substrate (e.g., a thin-film tile).

FIG. 14 illustrates a prior art wireless communication environment comprising different wireless communication systems, and which may include one or more mobile wireless devices.

FIG. 15 is a block diagram of a transceiver that might be used in a wireless device, such as a cellular telephone, and which may beneficially incorporate an embodiment of the present invention for improved performance.

FIG. 16 is a process flow chart showing a first method for fabricating a 3-dimensional integrated circuit.

FIG. 17 is a process flow chart showing a second method for fabricating a 3-dimensional integrated circuit.

FIG. 18 is a process flow chart showing a third method for fabricating a 3-dimensional integrated circuit.

FIG. 19 is a process flow chart showing a fourth method for fabricating a 3-dimensional integrated circuit.

FIG. 20 is a process flow chart showing a fifth method for fabricating a 3-dimensional integrated circuit.

Like reference numbers and designations in the various drawings indicate like elements.

### DETAILED DESCRIPTION

The present invention encompasses improved configurations of field-effect transistors (FETs), particularly within a low-noise amplifier (LNA), that reduces unwanted parasitic capacitances, inductances, and/or resistances (collectively, “parasitics”). Embodiments of the present invention take advantage of the characteristics of a stacked-pair of ICs in a 3-dimensional (3D) configuration to beneficially assign FETs of various LNA circuit designs to different ones of the paired ICs within the 3D stack. Advantages include optimizing the performance of the circuitry within each IC in the 3D stack and reducing parasitics by shortening routing distances between circuit elements within each IC of the 3D stack and reducing conductor overlaps.

A number of 3-D technologies have been developed that have focused on stacking and bonding aligned IC dies originally fabricated on different wafers (also known as wafer-to-wafer bonding), stacking and bonding individual IC dies on non-singulated IC dies on a wafer (also known as die-to-wafer bonding), and stacking and bonding an individual IC die on another IC die (also known as die-to-die bonding). One such technology may be referred to as “hybrid bonding interconnect” (HBI), in which circuitry is fabricated on different wafers or dies and then vertically stacked and interconnected in a 3-D structure. Bonding of the two wafers/dies is generally between both dielectric materials (e.g., silicon dioxide, SiCN, SiCOH, and/or analogous alloys) and conductive interconnect materials (e.g., copper, aluminum, and/or their alloys). In general, a high density of interconnects between the top and bottom wafers/dies is desirable to achieve good communications between them. The interconnect pitch can be between about 0.2 to 10 μm, and preferably in approximately the 2-5 μm range. HBI technology has demonstrated high interconnect density, is a planar technology that does not require underfill or carrier wafer integration, and enables formation of interconnects between two stacked IC wafers/dies during the bonding stage of processing at relatively low temperatures (e.g., <400° C.).

Another stacking-and-bonding technology utilizes thermo-compression bonding of pillar bumps on mated ICs. Thermo-compression bonding is also referred to as diffusion bonding, pressure joining, thermocompression welding, or solid-state welding. Pillar bumps may be made of copper with a contact-end coated in nickel and then silver or tin (e.g., solder). Two IC chips that include corresponding aligned pillar bumps are stacked together while applying force and heat simultaneously, thereby creating an electrical coupling between mated conductors. Atoms migrate between the metallic crystal lattices of the two components based on crystal lattice vibration, which adheres the interfaces together. This method enables direct electrical interconnection between two structures without additional steps.

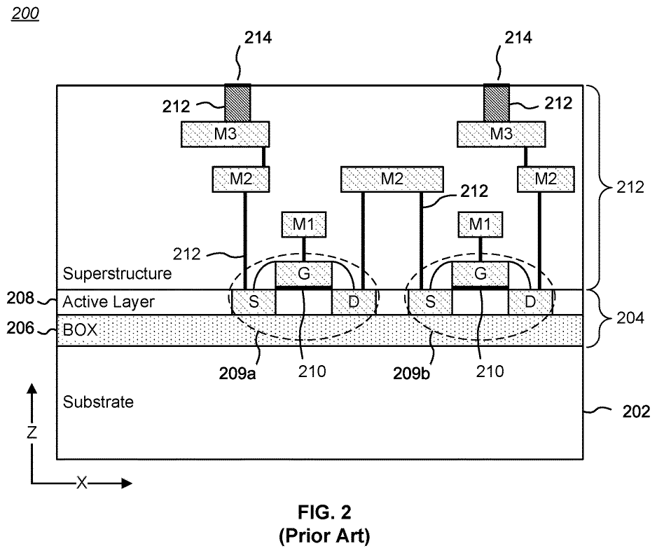

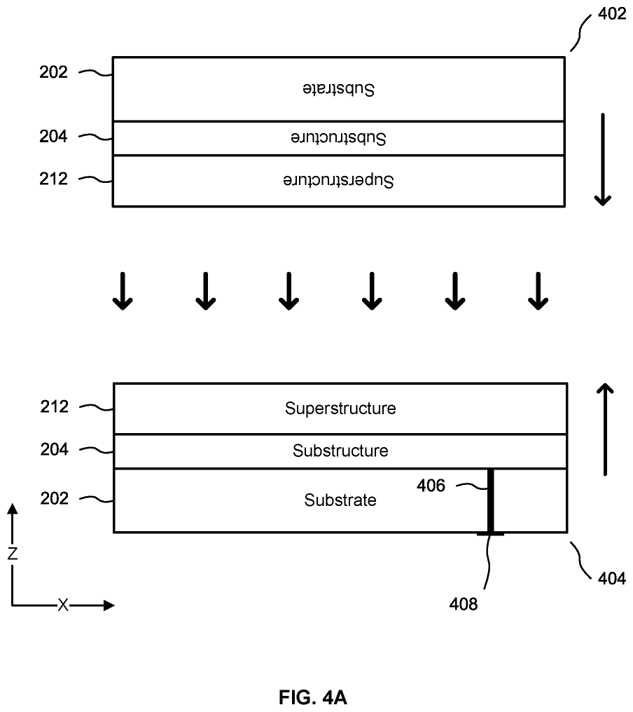

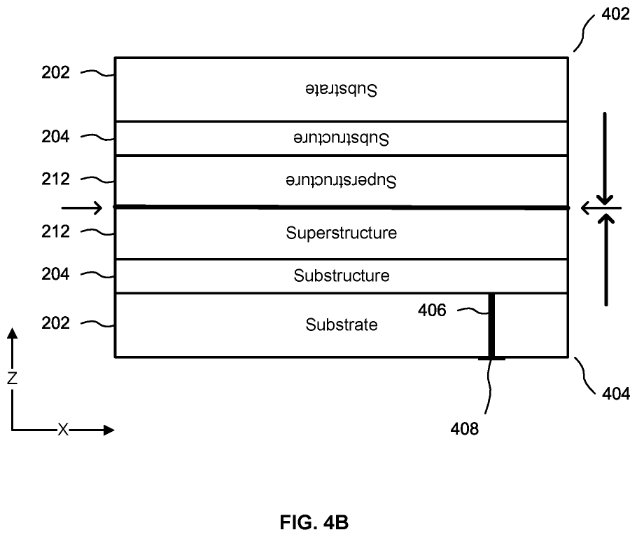

FIG. 4A is a cross-sectional view of two ICs 402, 404 in the process of being bonded together into a 3D IC stack. The two ICs 402, 404 each may be similar to the SOI IC 200 shown in FIG. 2, but may be of different types; for example, IC 402 may be an SOI IC or trap rich (TR) silicon (Si) IC, while IC 404 may be a bulk Si IC or a high-resistivity (HR) bulk Si IC. The “upper” IC 402 has been inverted so that its superstructure 212 may be aligned with and bonded to the superstructure 212 of the “lower” IC 404. Bonding may be by any suitable method, including HBI and thermo-compression bonding of pillar bumps. One or both of the substrates 202 of the ICs 402, 404 may include “through-substrate vias” (TSVs) 406 fabricated so that each TSV 406 passes through the substrate between the corresponding substructure 204 and an electrical connection point, such as a bond pad 408 (only the lower IC 404 is illustrated as having a TSV 406).

FIG. 4B is a cross-sectional view of the two ICs 402, 404 of FIG. 4A after being bonded together into a 3D IC stack. The bond-line between the two ICs 402, 404 is indicated by the horizontal arrows.

FIG. 4C is a cross-sectional view of a variant configuration of the two ICs 402, 404 of FIG. 4A after being bonded together into a 3D IC stack. In the illustrated embodiment, the IC substrate 202 of the upper IC 402 has been removed partially or completely (e.g., by grinding, chemical or ion etching, chemical separation, or chemical-mechanical polishing) to expose the backside of the substructure 204 of the upper IC 402. Some back-end of line (BEOL) fabrication processes or post-BEOL fabrication processes (e.g., Outsourced Semiconductor Assembly and Test, or “OSAT”) allow application of a redistribution layer (RDL), which is generally an extra patterned conductive layer (commonly aluminum) on an IC die that makes the input/output (I/O) pads of an IC die available to be coupled to other locations of the die, and/or to another IC die, and/or to specialized packaging structures. In the example shown in FIG. 4C, an optional RDL 410 has been formed on the exposed backside of the substructure 204 of the upper IC 402. Portions of the RDL 410 may be used to connect to various circuit elements (e.g., FETs) or signal paths within the adjacent substructure 204 as well as within the superstructure 212. An advantage of using RDL 410 for such connections is that the connection pitch can be much finer in RDL compared to the pitch required for TSVs.

Note that an advantage of using SOI ICs for 3D stacking is that it is easier to remove the substrate 202 than in bulk Si ICs because of the defined etch stop presented by the BOX layer 206 in an SOI IC. With bulk Si, there is no defined place for etching to stop.

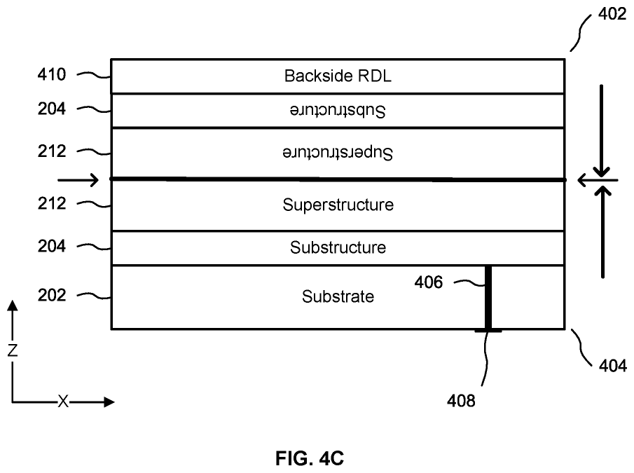

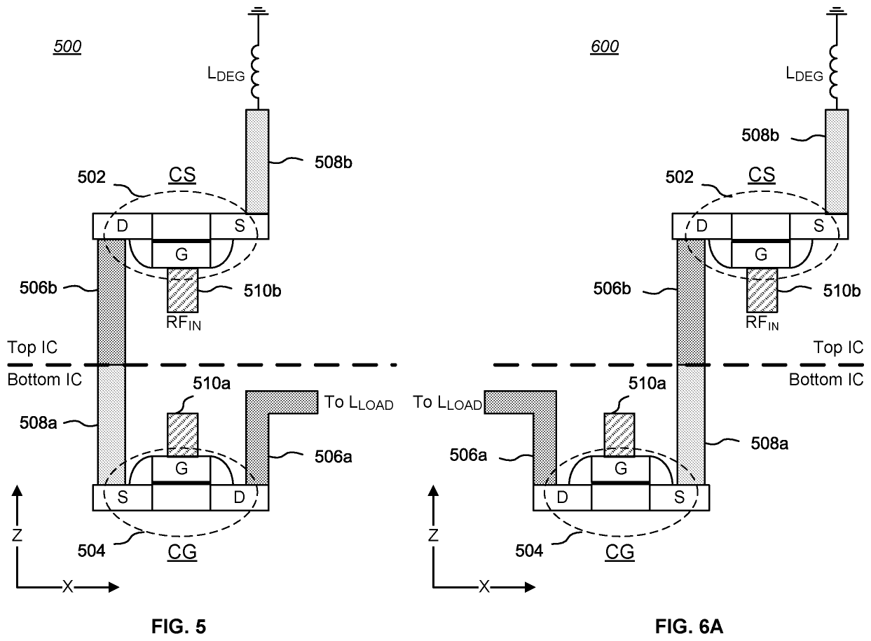

FIG. 5 is a cross-sectional view of a portion of a 3D IC stack 500 showing a first embodiment of an LNA circuit configuration. In the illustrated example, a common source (CS) FET device (within dashed oval 502) is formed within a top IC (e.g., the upper IC 402 shown in FIGS. 4B and 4C) and a common gate (CG) FET device (within dashed oval 504) is formed within a bottom IC (e.g., the lower IC 404 shown in FIGS. 4B and 4C); the heavy dashed line shows the bonding line between the top and bottom ICs. In the illustrated example, the CS FET is substantially vertically aligned with the CG FET along the Z axis of the 3D IC stack 500.

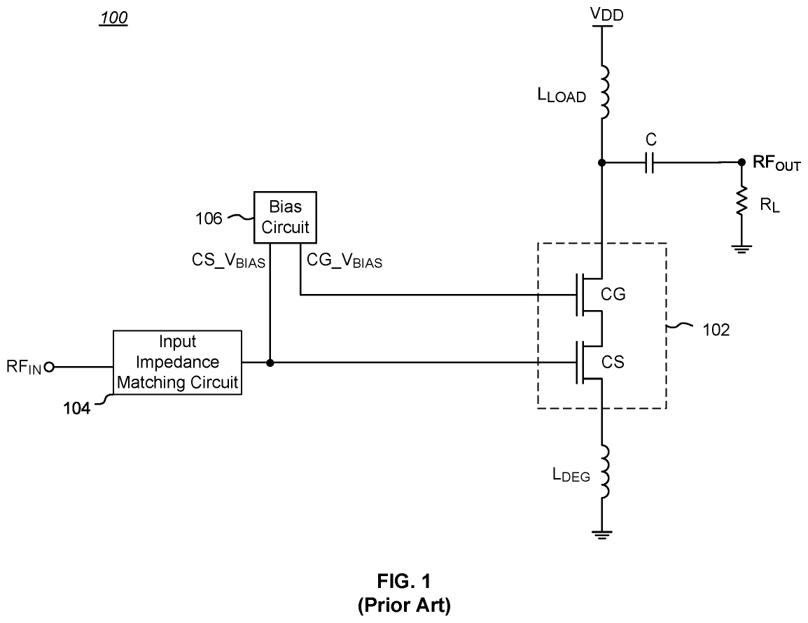

A drain signal path 506a is coupled to the drain D of the CG FET and is configured to be coupled to output circuitry, such as a load inductor L_{LOAD}. A source signal path 508a is coupled to the source S of the CG FET and to a drain signal path 506b coupled to the drain D of the CS FET. A source signal path 508b is coupled between the source S of the CS FET and (in this example) to a degeneration inductor L_{DEG}. In the illustrated example, the gates G of the CG FET and CS FET may be coupled to suitable bias circuitry (not shown, but see FIG. 1) through corresponding gate signal paths 510a, 510b. The gate signal path 510b of the CS FET may be coupled to an RF_{IN} signal, directly or indirectly (e.g., through an input impedance matching circuit). The various drain, source, and gate signal paths may comprise conductive vias, TSVs, portions of one or more metallization layers, or a combination of such conductors.

In some embodiments, it may be advantageous to fabricate the CS FET in the top IC using an SOI fabrication process to improve RF signal sensitivity, and to fabricate the CG FET in the bottom IC using a bulk Si process to avoid the floating body (kink) effects generally inherent in devices made using the SOI fabrication process. It may also be advantageous to fabricate other, post-LNA circuitry (particularly digital circuitry) in the lower, bulk Si IC. However, in some applications, it may be advantageous to fabricate the CG FET in the top IC and the CS FET in the bottom IC. In some embodiments, it may be advantageous to fabricate sets of CG/CS FETs in combinations of top and bottom IC placements, such as a CG top/CS bottom for one set and a CS top/CG bottom for another set.

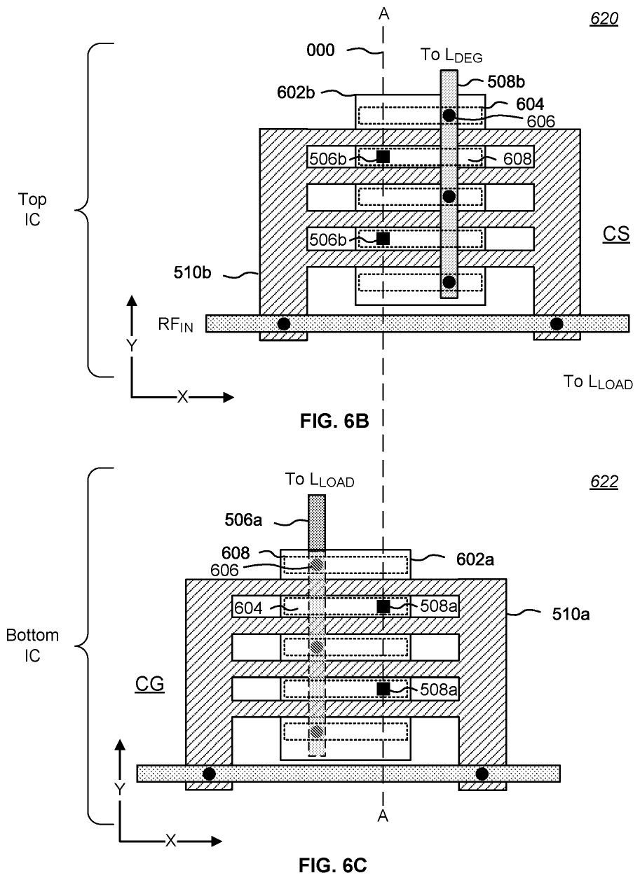

FIG. 6A is a cross-sectional view of a portion of a 3D IC stack 600 showing a second embodiment of an LNA circuit configuration. Similar in most aspects to the embodiment shown in FIG. 5, the CG FET in the bottom IC is offset laterally from the CS FET in the top IC so as to further reduce the influence of the two FETs on each other, thus further reducing parasitics.

Mating two different ICs, each containing a portion of an LNA circuit, to form a 3D stack allows device layouts that avoid some or all overlapping of the conductive signal paths to the drain, source, and gate of constituent FETs. For example, FIG. 6B is a top-down plan view of an example layout for a CS FET 620 (corresponding to the CS FET in FIG. 6A) within a top IC. FIG. 6C is a top-down plan view of an example layout for a CG FET 622 (corresponding to the CG FET in FIG. 6A) within a bottom IC.

In FIGS. 6B and 6C, the gate signal paths 510a, 510b overlay respective gates within the active regions 602a, 602b of respective IC substrates. In FIG. 6B, the source fingers 604 (shown in dotted outline) of the CS FET are connected by vias 606 to a source signal path 508b that is perpendicular to extents of the gate signal path 510b, and thus minimally interacts with the gate signal path 510b. Similarly, in FIG. 6C, the drain fingers 608 (shown in dotted outline) of the CG FET are connected by a drain signal path 506a that is perpendicular to extents of the gate signal path 510a, and thus minimally interacts with the gate signal path 510a.

Because the top IC is stacked on the bottom IC in a 3D configuration, the drain fingers 608 (shown in dotted outline) of the CS FET may be connected to the source fingers 604 (shown in dotted outline) of the CG FET by means of vias. For example, the drain signal paths 508a of the CG FET may comprise vias (shown as squares) that connect vertically through the 3D stack to corresponding vias (shown as squares) comprising the source signal paths 506b of the CS FET, with the respective vias being aligned along line A-A; that is, the layout of FIG. 6B would be formed in the top IC so as to lay over the layout of FIG. 6C formed in the bottom IC so that bonding would occur between the vias comprising the source signal paths 506b and the drain signal paths 508a. A similar set of layouts may be used for the CS FET and CG FET of FIG. 5, with the layout of FIG. 6C flipped along its vertical axis.

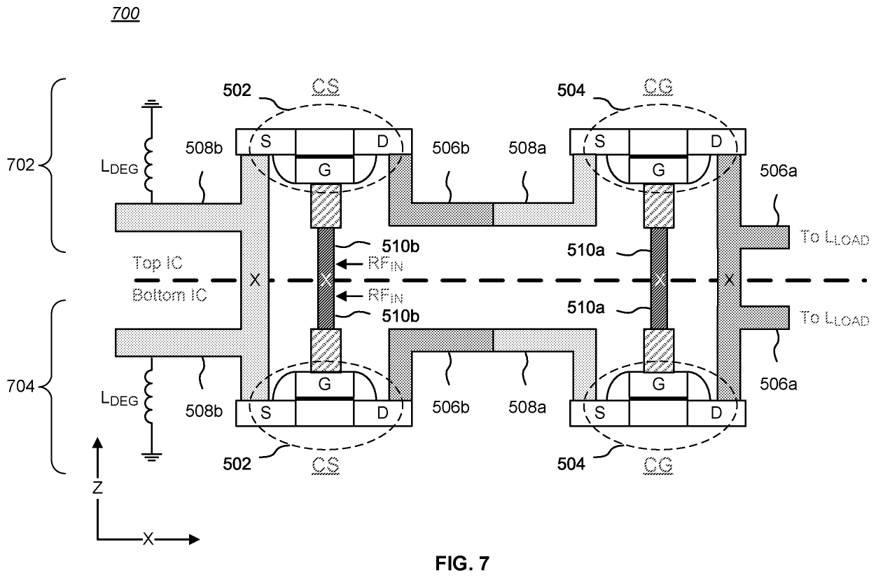

Stacking ICs in a 3D configuration provides numerous alternative design choices. For example, FIG. 7 is a cross-sectional view of a portion of a 3D IC stack 700 showing an embodiment of a dual-LNA circuit configuration. Elements are referenced the same as in FIG. 5. The top IC includes a first LNA circuit 702 comprising a CS FET connected in series with a CG FET. Similarly, the bottom IC includes a second LNA circuit 704 comprising a CS FET connected in series with a CG FET. By aligning and bonding the top IC to the bottom IC, common connections are made between the source signal paths 508b of the CS FETs, the gate signal paths 510b of the CS FETs, the gate signal paths 510a of the CG FETs, and the drain signal paths 506a of the CG FETs.

Advantages of the layout shown in FIG. 7 include: placement of the input CS FET and cascode CG FET in a more compact configuration in the X dimension compared to conventional 2D layouts; the gate of the CS FET may be placed close to the RF_{IN} input while the drain of the CG FET may be placed close to the output of the LNA; parasitic coupling is reduced by shortening routing distances between circuit elements within each IC of the 3D stack and reducing conductor overlaps; and the length of the gate signal paths 510a, 510b can be short, thus reducing loss.

The first LNA circuit 702 and the second LNA circuit 704 may be operated in parallel to amplify one RF input signal. In an alternative configuration, the operation of the dual LNA circuits 702, 704 may be dynamically settable to operate only the first LNA circuit 702, only the second LNA circuit 704, or both LNA circuits 702, 704. For example, by not coupling the gate signal paths 510a of the top IC and bottom IC CG FETs together, and by selectively controlling the bias voltage to the gates of those FETs, the ON-OFF state of those FETs may be independently controlled. Thus, for example, the top IC CG FET may be biased OFF while the bottom IC CG FET is biased ON, leaving only the second LNA circuit 704 operational. Such a configuration may be useful for a first, lower gain mode. Both the top IC CG FET and the bottom IC CG FET may be biased ON, allowing parallel operation of the dual first and second LNA circuits 702, 704. Such a configuration may be useful for a second, higher gain mode. The bottom IC CG FET may be biased OFF while the top IC CG FET is biased ON, leaving only the first LNA circuit 702 in the top IC operational. If the top IC is SOI based and the bottom IC is bulk Si based, then the first LNA circuit 702 may inherently have a higher gain than the second LNA circuit 704, and thus turning only the top IC CG FET to an ON state may also provide a higher gain mode. Alternatively, switches (such as at nodes marked “X”) may be included to selectively route RF signals to only the first LNA circuit 702, only the second LNA circuit 704, or both LNA circuits 702, 704.

In some embodiments, the illustrated input CS FETs and/or the output CG FETs may be a single shared transistor implemented on a single die. In some embodiments, the one or more input CS FETs may all be implemented on a first die and the one or more output CG FETs may all be implemented on a second die. In some embodiments, all of the switches may be implemented on a first die; alternatively, some switches may be implemented on a first die and other switches may be implemented on a second die.

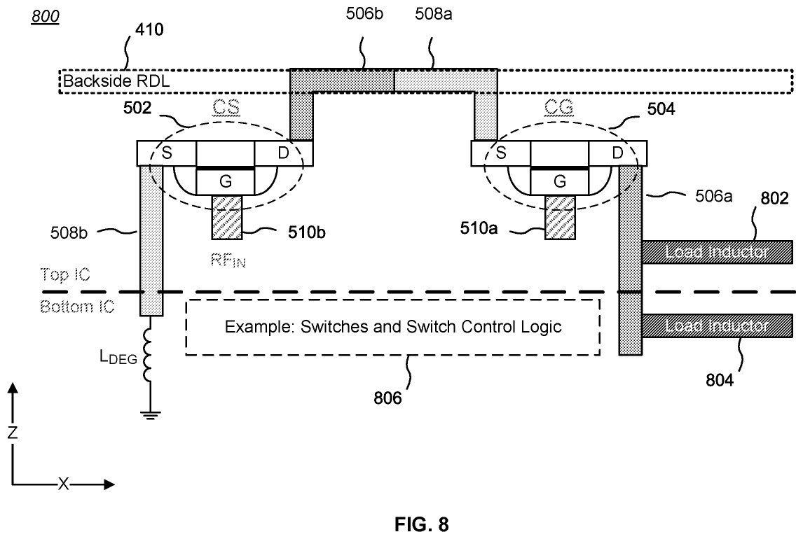

FIG. 8 is a cross-sectional view of a portion of a 3D IC stack 800 showing a first embodiment of an LNA circuit configuration that includes integrated inductance elements. Most elements are referenced the same as in FIG. 5. In the illustrated example, both the CS and CG FETs are fabricated in the top IC. The drain signal path 506b for the CS FET and the source signal path 508a for the CG FET are shown as connecting to the respective CS FET drain D and CG FET source S from the backside of the top IC (rather than from the frontside superstructure 212 of the top IC—see FIG. 4C), and accordingly the top IC generally should be configured like the 3D stack shown in FIG. 4C, with backside RDL 410 available for making connections to the substructure 204 of the top IC.

In addition, a first integrated inductance 802 is also fabricated in the superstructure of the top IC and connected to the drain signal path 506a of the CG FET. The drain signal path 506a of the CG FET may also be coupled to a second integrated inductance 804 fabricated in the superstructure of the bottom IC. The first and second integrated inductances 802, 804 may each comprise, for example, a planar coil of conductive material (e.g., part of one of the metallization layers within the corresponding IC superstructure 212) or may simply comprise the parasitic inductance of the conductive signal path routing. The source S of the CS FET is shown connected to a schematic degeneration inductor L_{DEG}, which may comprise, for example, a planar coil of conductive material or the parasitic inductance of the conductive signal path routing, or be an off-chip discrete inductor.

FIG. 8 also shows that one of the ICs (the bottom IC in the illustrated example) may contain other components 806 useful in an LNA circuit, such as switches, switch control logic, and/or other RF components.

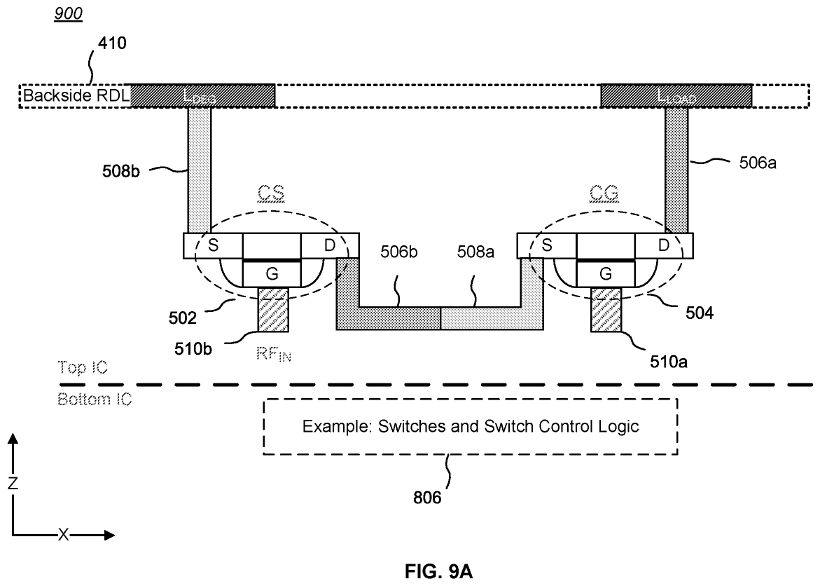

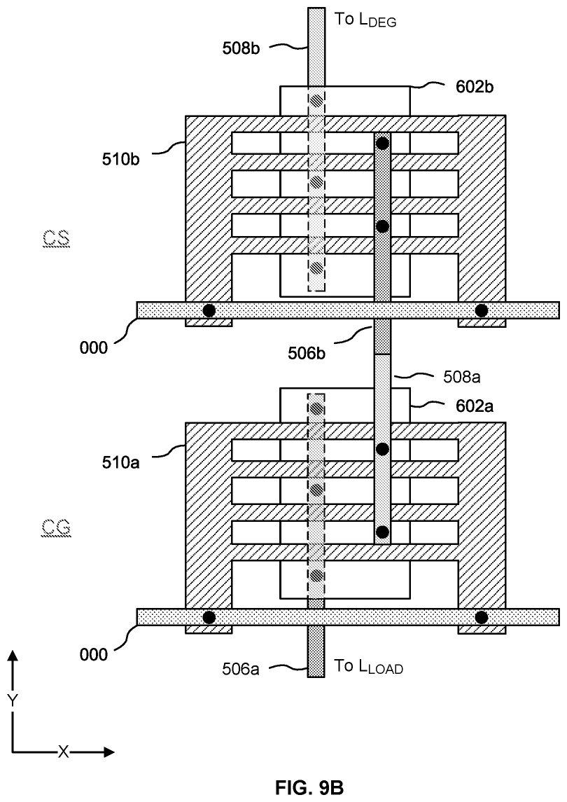

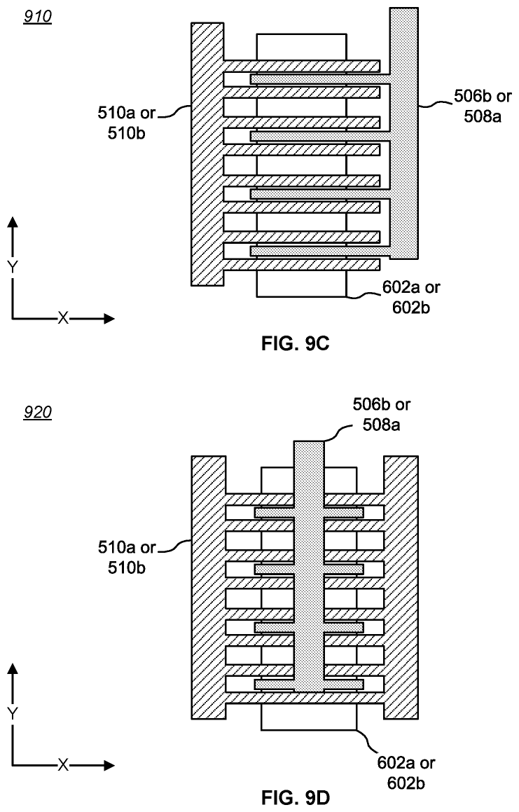

FIG. 9A is a cross-sectional view of a portion of a 3D IC stack 900 showing a second embodiment of an LNA circuit configuration that includes integrated inductance elements. Most elements are referenced the same as in FIG. 8. In the example 3D IC stack 900, the drain signal path 506a for the CG FET and the source signal path 508b for the CS FET are connected to the respective CG FET drain D and CS FET source S from the backside of the top IC. Accordingly, the top IC generally should be configured like the 3D stack shown in FIG. 4C, with backside RDL 410 available for making connections to the substructure 204 of the top IC.

In the illustrated example, a load inductance L_{LOAD} is connected to the drain signal path 506a of the CG FET, and a degeneration inductance L_{DEG} is connected to the source signal path 508b of the CS FET. The inductances may be implemented in the RDL 410 as a planar coil of conductive material or the parasitic inductance of the conductive signal path routing. Alternatively, the inductances may comprise an off-chip discrete inductor connected to contact pads formed in the RDL 410.

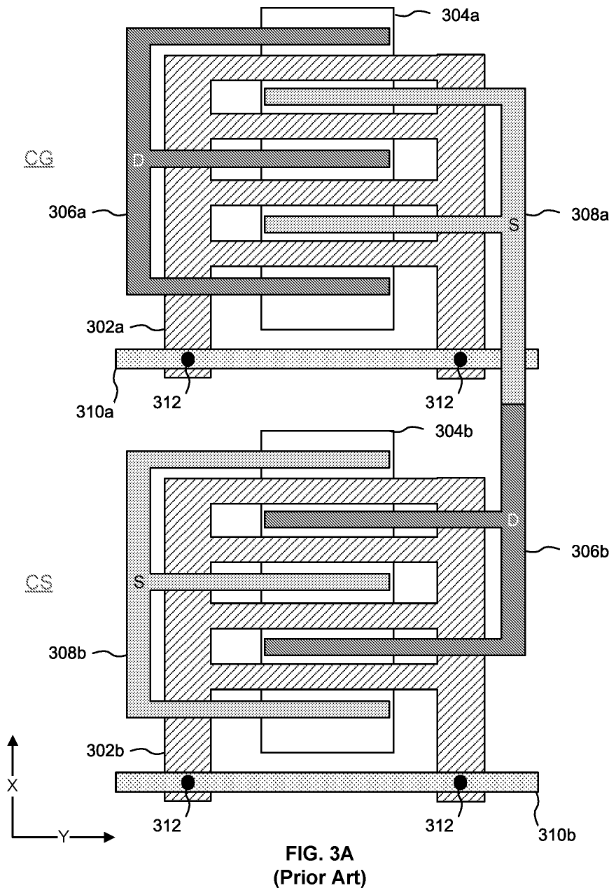

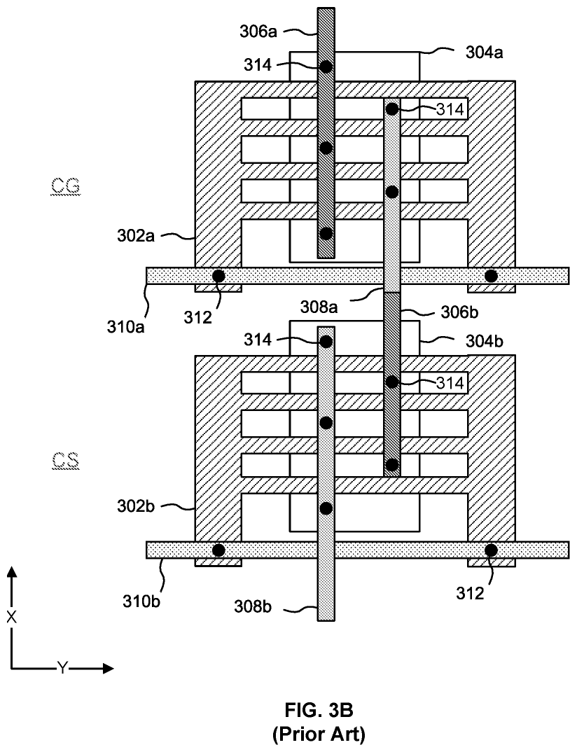

FIG. 9B is a bottom-up plan view of a pair of FETs CG and CS (corresponding to the CG FET and the CS FET in FIG. 9A) in a first 2D layout within a top IC. Thus, the drain signal path 506a for the CG FET and the source signal path 508b for the CS FET, shown in partial phantom (dashed-line) view, are on the RDL 410 side of the top IC of FIG. 9A. Conversely, the drain signal path 506b for the CS FET and the source signal path 508a for the CG FET face the bottom IC of FIG. 9A. Compared to the conventional layout shown in FIG. 3B, there is reduced drain-gate and source-gate coupling in the illustrated configuration since the drain signal path 506a for the CG FET and the source signal path 508b for the CS FET are connected to the respective CG FET drain D and CS FET source S from the backside (RDL 410 side) of the top IC.

FIG. 9C is a bottom-up plan view of a FET (which may correspond to either of the CG FET or the CS FET in FIG. 9A) in a second 2D layout within a top IC. This view shows that the gate signal path (e.g., 510a or 510b in FIG. 9A) does not cross over the source or drain signal paths (e.g., drain signal path 506a or source signal path 508b in FIG. 9A). The corresponding drain or source signal paths (e.g., drain signal path 506b or source signal path 508a in FIG. 9A; not shown to avoid clutter) would be on the RDL 410 side of the top IC. Accordingly, there is reduced drain-gate or source-gate coupling compared to the conventional layout shown in FIG. 3A.

FIG. 9D is a bottom-up plan view of a FET (which may correspond to either of the CG FET or the CS FET in FIG. 9A) in a third 2D layout within a top IC. This view shows that the gate signal path (e.g., 510a or 510b in FIG. 9A) and the source or drain signal paths (e.g., drain signal path 506a or source signal path 508b in FIG. 9A) crossover. The corresponding drain or source signal paths (e.g., drain signal path 506b or source signal path 508a in FIG. 9A; not shown to avoid clutter) would be on the RDL 410 side of the top IC. An advantage of the configuration shown in FIG. 9D is lower resistance to the drain/source of the FET due to the central position of the vertical member of the drain/source signal path 506a, 508b with respect to the horizontal members of the drain/source signal path 506a, 508b.

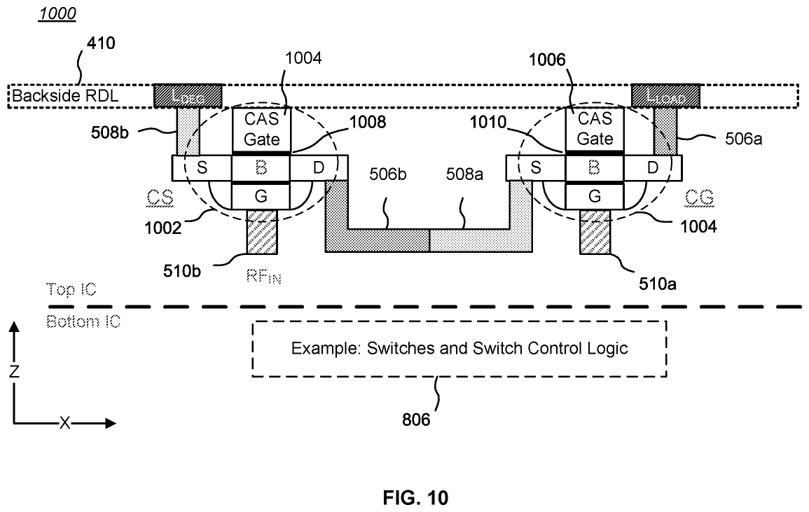

FIG. 10 is a cross-sectional view of a portion of a 3D IC stack 1000 showing a third embodiment of an LNA circuit configuration that includes integrated inductance elements. Most elements are referenced the same as in FIG. 9A. However, the CS FET 1002 and the CG FET 1004 each include a respective conductive aligned supplemental (CAS) gate 1004, 1006 formed adjacent to the body B of a primary FET comprising a conventional source S, gate G, and drain D. Each CAS gate 1004, 1006 is separated from the “back side” of a corresponding primary FET by a dielectric layer 1008, 1010 (e.g., SiO₂). Each CAS gate 1004, 1006, the corresponding dielectric layer 1008, 1010 and the corresponding source S and drain D of the primary FET, forms a controllable MOSFET, with independent control provided by the CAS gate 1004, 1006. Accordingly, a control voltage applied to a CAS gate 1004, 1006 can regulate the electrical characteristics of the regions of the corresponding primary FET.

By applying control voltages to a CAS gate (typically DC voltages), various effects can be induced in and around the body B of the corresponding primary FET. For example, FETs that include a CAS gate generally have a higher voltage capability than conventional FETs due to the ability to bias the CAS gate such that the body B is more depleted than can be accomplished by the primary gate G alone. As another example, FETs that include a CAS gate generally have a lower ON resistance (R_{ON}) than conventional FETs due to the ability to bias the CAS gate such that the body B is more enhanced than can be accomplished by the primary gate G alone, resulting in lower insertion loss as well as a higher current capacity without increasing heat generation. As yet another example, FETs that include a CAS gate may have lower leakage currents in subthreshold operating conditions due to the ability to bias the back-channel region of the body B in a fully OFF condition. Another benefit of FETs having a CAS gate is that multiple FET devices can be identically fabricated (e.g., same implant doping levels) but controlled by respective CAS control voltages to operate with either the same or different threshold voltages, V_{T}. For example, in some applications, it may be useful to have some FETs with a lower V_{T} while other FETs have a higher V_{T}. This can be achieved by biasing the CAS gates of such FETs with different voltage values, which leads to the otherwise identical FETs exhibiting different threshold voltages V_{T}. Notably, all of these benefits are available from the same FET under different operating conditions, just by varying the bias voltage applied to its CAS gate. In particular, the threshold voltages V_{T} of a CG and/or a CS FET may be dynamically shifted by a suitable control circuit to vary the gain characteristics of an LNA on the fly. The control circuit may be, for example, part of the components 806 block shown in FIG. 9A.

Further details on the fabrication and usage of CAS gates may be found in U.S. Pat. No. 10,580,903, issued Mar. 3, 2020, entitled “Semiconductor-On-Insulator Transistor with Improved Breakdown Characteristics”, assigned to the assignee of the present invention, the contents of which are incorporated by reference.

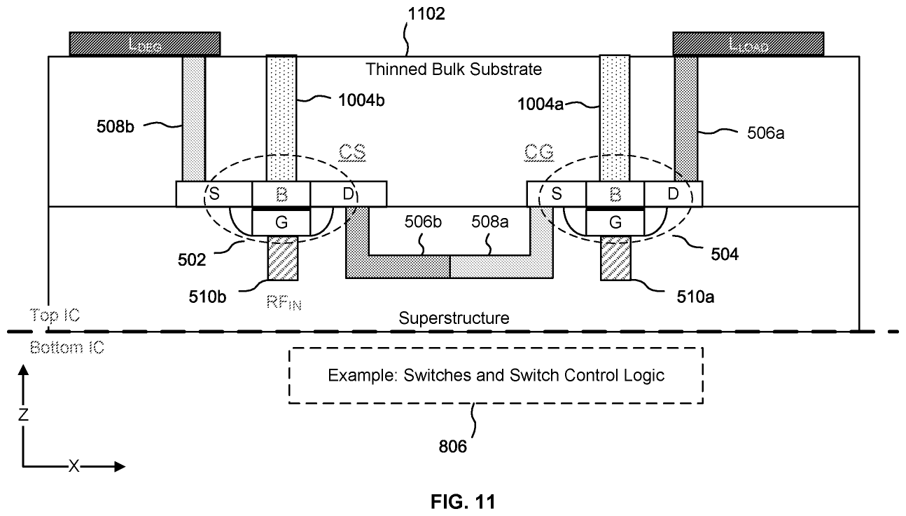

FIG. 11 is a cross-sectional view of a portion of a 3D IC stack 1100 showing a fourth embodiment of an LNA circuit configuration that includes inductance elements. Most elements are referenced the same as in FIG. 9A. However, the top IC is fabricated using a bulk Si process, and the substrate 1102 has been thinned, such as by chemical-mechanical polishing, and the inductances L_{DEG} and L_{LOAD} are shown (by way of example only) as being discrete inductors. In one example embodiment, the substrate 1102 is thinned to between about 1 μm and about 4 μm. Conductive TSVs 1004 a, 1004 b are fabricated to connect from the exposed backside surface of the thinned substrate 1102 to or near to the respective bodies B of the CG FET and the CS FET; note that TSVs 1004a, 1004b would be isolated from other circuitry by known means, such as trench isolation structures, not shown.

Control voltages applied to the TSVs 1004a, 1004b can bias the respective bodies B of the CG FET and/or the CS FET and thereby regulate the electrical characteristics of the regions of the corresponding FETs. For example, a control circuit (which may be, for instance, part of the components 806 block shown in FIG. 11) can dynamically change the bias voltages to the respective bodies B of the CG FET and/or the CS FET, thereby changing the threshold voltages V_{T} of either or both FETs and/or remove all of floating body effects inherent in the FETs. The FETs will still have independent bodies B.

For the embodiments shown in FIGS. 10 and 11, the ability to shift the threshold voltage V_{T} of the CG FET in particular has a number of advantages. For example, in a low-gain mode of operation for an LNA, decreasing the V_{T} of the CG FET should generally improve linearity and result in more headroom for the input CS FET compared to the cascode CG FET due to the resulting decreased gate voltage V_{GS} for the CG FET. Decreasing V_{GS} for the CG FET increases the voltage of the source S of the CG FET (which is the drain D of the CS FET), thus increasing the headroom for the CS FET. In addition, the V_{T} of the CS FET may be dynamically shifted to enable different gain modes (e.g., low, medium 1, medium 2, high) with minimal impact to the RF signal path.

Another application of a variable V_{T} is to control the work function of high-k gates (e.g., HfO₂ gates). For example, applying a higher voltage to shift the V_{T} also shifts the high-k gate work function a little bit. Thus, the work function of the CS FET and/or the CG FET may be controlled in essentially a continuous analog way (if the gate voltage V_{G} is kept low enough to not allow the device to shift on the fly in an uncontrollable way).

As the examples above should indicate, there are many ways to connect to the source S and drain D of a CS FET and CG FET comprising components of an LNA: both contacted from the front, both contacted from the back, and one contacted from the front with the other contacted from the back.

The examples above also indicate that a CS FET and CG FET comprising components of an LNA may be configured in different ways: the CG and CS FETs both within the same IC (top or bottom), and/or the CG and CS FETs each within different ICs (top and bottom) in a 3D IC stack. There are a number of combinations of fabrication technologies that may be used for the wafers comprising the top and bottom ICs, including: both wafers are bulk Si and/or HR bulk Si IC; both wafers are SOI and/or trap rich Si; one wafer is bulk Si and/or HR bulk Si IC and the other wafer is SOI and/or trap rich Si; or one wafer is bulk Si, HR bulk Si IC, SOI, and/or trap rich Si, and the other wafer is an exotic (not primarily Si) substrate, such as a SiGe, GaAs, GaN, InP, etc., which may be particularly useful at higher radio frequencies, such as above about 1 GHz. Further, different types of transistor technologies may be combined by fabricating a first type of device (e.g., MOSFET and FET variations, for example, for switches and control circuits) in one wafer and a second type of device (e.g., bipolar junction transistor, for example, for amplifiers) in the other wafer, where the wafer fabrication technology may be the same or differ, as described above.

When the CG and CS FETs are on different wafers, there is a linearity advantage by locating the CG FET in a bulk Si wafer. When the CG and CS FETs are on different wafers, the thickness of the respective gates oxides for the CG and CS FETs may differ; for example, it may be advantageous to use a thinner gate oxide for the CS FET in one wafer, and a thicker gate oxide for the CG FET in the other wafer of a 3D IC stack.

A 3D IC stack for an LNA allows full exploitation of the X, Y, and Z dimensions of the stack for component placement. For example, the degeneration inductor L_{DEG} may be external to the 3D IC stack (e.g., in a common circuit module or on a printed circuit board) while the load inductor L_{LOAD} may be integrally fabricated as part of the top IC or bottom IC, or vice versa. Spacing apart the two inductors prevents or reduces their inter-coupling and allows the load inductor L_{LOAD} to be spaced away from the RF input, reducing or eliminating adverse interactions.

A 3D IC stack (i.e., a single bumped die) for an LNA also results in a 2D “footprint” size reduction (with more content) compared to a conventional 2D LNA IC.

By splitting the circuitry and functionality of an LNA between a top IC and a bottom IC of a 3D IC stack, the ICs—and even individual components, particularly FETs—may be separately optimized, which provides design flexibility and may shorten time to market for new products. For example, the top IC may be optimized to support a high-performance specialized technology for a product line, such as high performance or specialized devices for an LNA, while the bottom IC may include inexpensive, common/generic technology, such as generic RF components and common or standard circuit blocks.

Bonding two ICs into a 3D IC stack enables some additional advantages that are useful to building LNA circuits. For example, one or both of the inductors L_{DEG} and L_{LOAD} described above, as well as other inductors that may be useful in an LNA circuit, may be integrally formed in the top IC or the bottom IC as 2D spirals. However, the skin depth effect that is prominent at higher frequencies (e.g., at or above about 1 GHZ) reduces the Q factor of a spiral inductor. However, the presence of two bonded ICs in a 3D IC stack enables fabrication of non-planar inductors, such as a 3D helical structure that goes up and down along the Z axis of a 3D IC stack crossing in/out of the top IC and bottom IC wafers, and spirals along a line within the X-Y plane of the 3D IC stack.

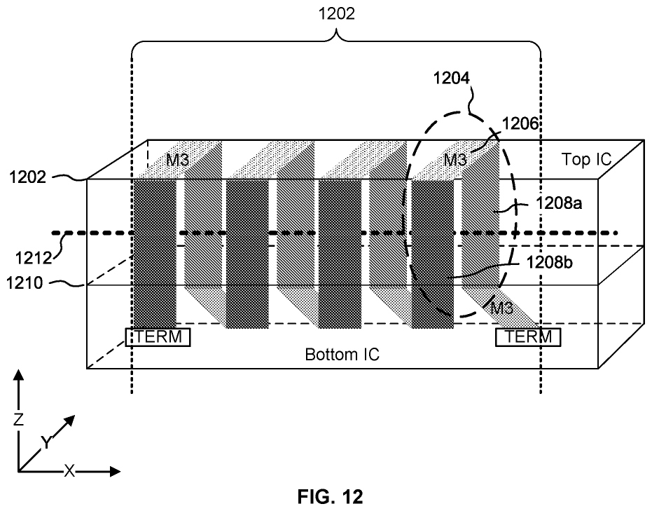

For example, FIG. 12 is a perspective view of a helical inductor 1200 fabricated as part of a 3D IC stack 1202. Both a top IC and a bottom IC include one or more partial loops of conductive material. For example, one such partial loop 1204 is shown within a dashed oval in the top IC. A portion of the partial loop 1204 may be, for example, a section 1206 of the M3 metallization layer of the top IC. Another portion of the partial loop 1204 may be, for example, vias 1208a, 1208b connecting between the M3 metallization layer section 1206 and the interface 1210 between the top IC and the bottom IC. In the illustrated example, the vias 1208a, 1208 b are offset from each other along the X axis of the 3D IC stack 1202.

The partial loops of conductive material in the top IC connect to at least one corresponding partial loop in the bottom IC, forming the helical inductor 1200 as a 3D structure (spiraling around the line 1212 in this example). Two terminals TERM for the helical inductor 1200 may be both located within one IC (the bottom IC in the illustrated example), or a first terminal TERM may be in the top IC and a second terminal TERM may be in the bottom IC.

It should be appreciated that the 3D structure of the helical inductor 1200 may vary from the illustrated example. For example, the helical inductor 1200 may include portions that are at angles to each other, such as an “L” shape. Further, the sizes of the partial loops of conductive material need not be uniform. As should be clear, one or more helical inductors 1200 may be combined with “split IC” CS and CG FET circuits such as those disclosed above to create a fully integrated LNA within a 3D IC.

Circuits and devices in accordance with the present invention may be used alone or in combination with other components, circuits, and devices. Embodiments of the present invention may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

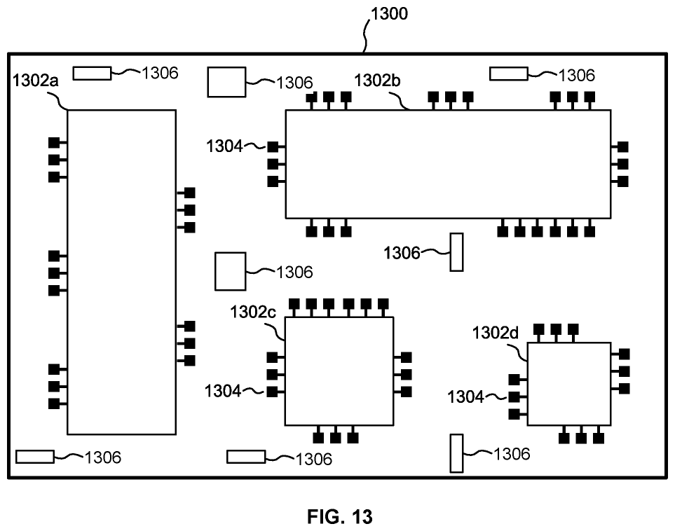

As one example of further integration of embodiments of the present invention with other components, FIG. 13 is a top plan view of a substrate 1300 that may be, for example, a printed circuit board or chip module substrate (e.g., a thin-film tile). In the illustrated example, the substrate 1300 includes multiple ICs 1302a-1302d having terminal pads 1304 which would be interconnected by conductive vias and/or traces on and/or within the substrate 1300 or on the opposite (back) surface of the substrate 1300 (to avoid clutter, the surface conductive traces are not shown and not all terminal pads are labelled). The ICs 1302a-1302d may embody, for example, signal switches, active and/or passive filters, amplifiers (including one or more LNAs), and other circuitry. For example, IC 1302b may incorporate one or more instances of a 3D LNA IC in accordance with the teachings of this disclosure.

The substrate 1300 may also include one or more passive devices 1306 embedded in, formed on, and/or affixed to the substrate 1300. While shown as generic rectangles, the passive devices 1306 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1300 to other passive devices 1306 and/or the individual ICs 1302a-1302d.

The front or back surface of the substrate 1300 may be used as a location for the formation of other structures. For example, one or more antennae may be formed on or affixed to the front or back surface of the substrate 1300; one example of a front-surface antenna 1308 is shown, coupled to an IC die 1302b, which may include RF front-end circuitry. Thus, by including one or more antennae on the substrate 1300, a complete radio may be created.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

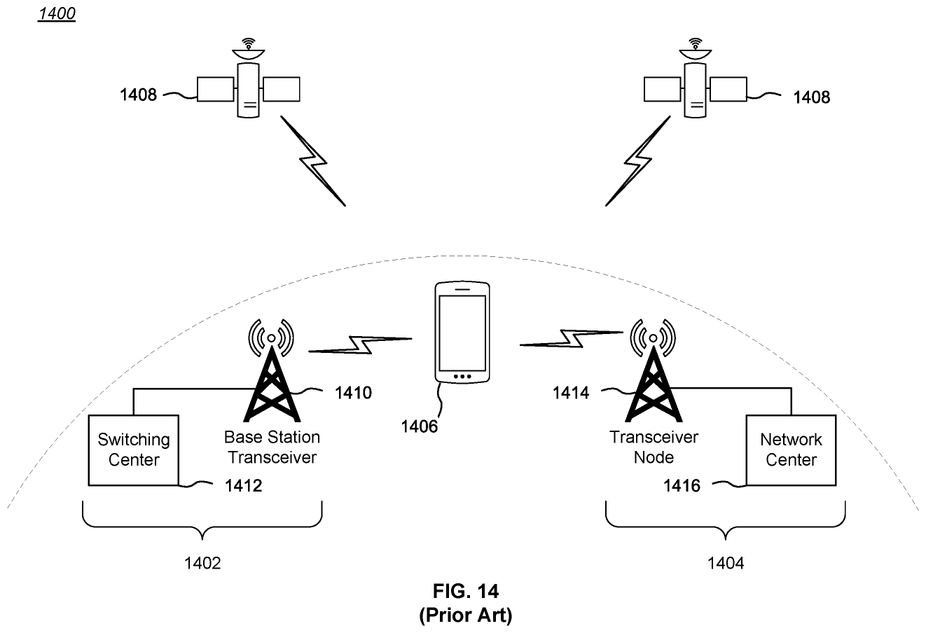

As an example of wireless RF system usage, FIG. 14 illustrates a prior art wireless communication environment 1400 comprising different wireless communication systems 1402 and 1404, and which may include one or more mobile wireless devices 1406. A wireless device 1406 may be a cellular phone, a wireless-enabled computer or tablet, or some other wireless communication unit or device. A wireless device 1406 may also be referred to as a mobile station, user equipment, an access terminal, or some other terminology known in the telecommunications industry.

A wireless device 1406 may be capable of communicating with multiple wireless communication systems 1402, 1404 using one or more of telecommunication protocols such as the protocols noted above. A wireless device 1406 also may be capable of communicating with one or more satellites 1408, such as navigation satellites (e.g., GPS) and/or telecommunication satellites. The wireless device 1406 may be equipped with multiple antennas, externally and/or internally, for operation on different frequencies and/or to provide diversity against deleterious path effects such as fading and multi-path interference.

The wireless communication system 1402 may be, for example, a CDMA-based system that includes one or more base station transceivers (BSTs) 1410 and at least one switching center (SC) 1412. Each BST 1410 provides over-the-air RF communication for wireless devices 1406 within its coverage area. The SC 1412 couples to one or more BSTs 1410 in the wireless system 1402 and provides coordination and control for those BSTs 1410.

The wireless communication system 1404 may be, for example, a TDMA-based system that includes one or more transceiver nodes 1414 and a network center (NC) 1416. Each transceiver node 1414 provides over-the-air RF communication for wireless devices 1406 within its coverage area. The NC 1416 couples to one or more transceiver nodes 1414 in the wireless system 1404 and provides coordination and control for those transceiver nodes 1414.

In general, each BST 1410 and transceiver node 1414 is a fixed station that provides communication coverage for wireless devices 1406, and may also be referred to as base stations or some other terminology known in the telecommunications industry. The SC 1412 and the NC 1416 are network entities that provide coordination and control for the base stations and may also be referred to by other terminologies known in the telecommunications industry.

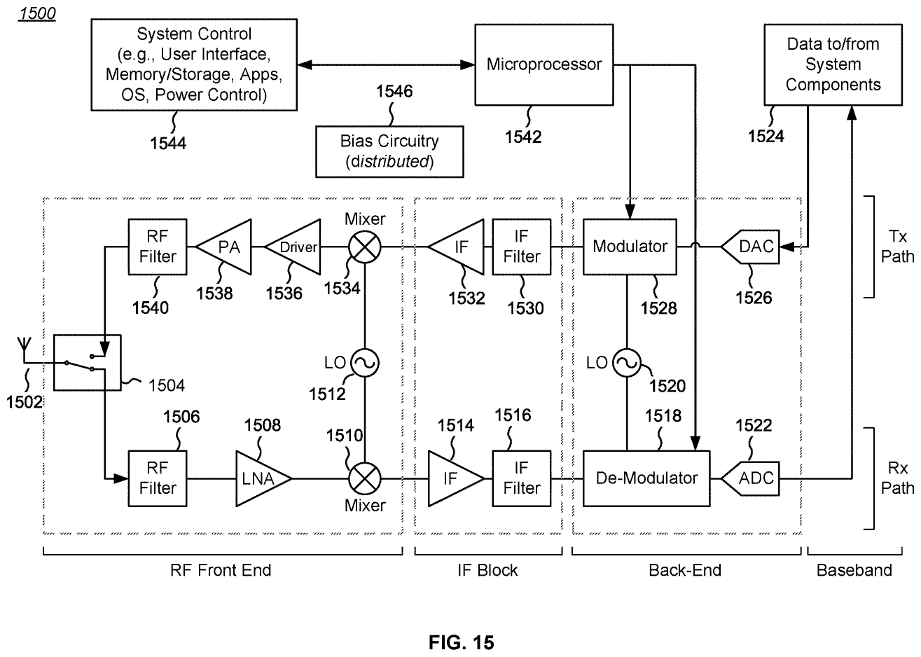

An important aspect of any wireless system, including the systems shown in FIG. 14, is in the details of how the component elements of the system perform. FIG. 15 is a block diagram of a transceiver 1500 that might be used in a wireless device, such as a cellular telephone, and which may beneficially incorporate an embodiment of the present invention for improved performance. As illustrated, the transceiver 1500 includes a mix of RF analog circuitry for directly conveying and/or transforming signals on an RF signal path, non-RF analog circuity for operational needs outside of the RF signal path (e.g., for bias voltages and switching signals), and digital circuitry for control and user interface requirements. In this example, a receiver path Rx includes RF Front End (RFFE), Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines TIN and TOUT (e.g., microstrips, co-planar waveguides, or an equivalent structure or circuit), either or both of which may have, for example, a 50 Ω impedance.

The receiver path Rx receives over-the-air RF signals through at least one antenna 1502 and a switching unit 1504, which may be implemented with active switching devices (e.g., field effect transistors or FETs) and/or with passive devices that implement frequency-domain multiplexing, such as a diplexer or duplexer. An RF filter 1506 passes desired received RF signals to at least one low noise amplifier (LNA) 1508a, the output of which is coupled from the RFFE Module to at least one LNA 1508b in the Mixing Block (through transmission line T_{IN} in this example). The LNA(s) 1508b may provide buffering, input matching, and reverse isolation. In some embodiments, the LNA(s) 1508a and 1508b may be a single LNA. In some embodiments, the LNA(s) 1508 a and 1508 b may be instances of a 3D IC LNA stack in accordance with the present invention.

The output of the LNA(s) 1508b is combined in a corresponding mixer 1510 with the output of a first local oscillator 1512 to produce an IF signal. The IF signal may be amplified by an IF amplifier 1514 and subjected to an IF filter 1516 before being applied to a demodulator 1518, which may be coupled to a second local oscillator 1520. The demodulated output of the demodulator 1518 is transformed to a digital signal by an analog-to-digital converter 1522 and provided to one or more system components 1524 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system components 1524 is transformed to an analog signal by a digital-to-analog converter 1526, the output of which is applied to a modulator 1528, which also may be coupled to the second local oscillator 1520. The modulated output of the modulator 1528 may be subjected to an IF filter 1530 before being amplified by an IF amplifier 1532. The output of the IF amplifier 1532 is then combined in a mixer 1534 with the output of the first local oscillator 1512 to produce an RF signal. The RF signal may be amplified by a driver 1536, the output of which is coupled to a power amplifier (PA) 1538 (through transmission line Tour in this example). The amplified RF signal may be coupled to an RF filter 1540, the output of which is coupled to at least one antenna 1502 through the switching unit 1504.

The operation of the transceiver 1500 is controlled by a microprocessor 1542 in known fashion, which interacts with system control components 1544 (e.g., user interfaces, memory/storage devices, application programs, operating system software, power control, etc.). In addition, the transceiver 1500 will generally include other circuitry, such as bias circuitry 1546 (which may be distributed throughout the transceiver 1500 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some components of the transceiver 1500 may be positioned in a different order (e.g., filters) or omitted. Other components can be (and often are) added, such as (by way of example only) additional filters, impedance matching networks, variable phase shifters/attenuators, power dividers, etc.

The current invention may improve performance (e.g., linearity and/or gain) of amplifier circuit modules or blocks. As a person of ordinary skill in the art will understand, a system architecture utilizing embodiments of the present invention is beneficially impacted in critical ways, including better range, better reception, lower power, wider bandwidth, and smaller size (owing to the smaller 2D footprint of a 3D IC stack).

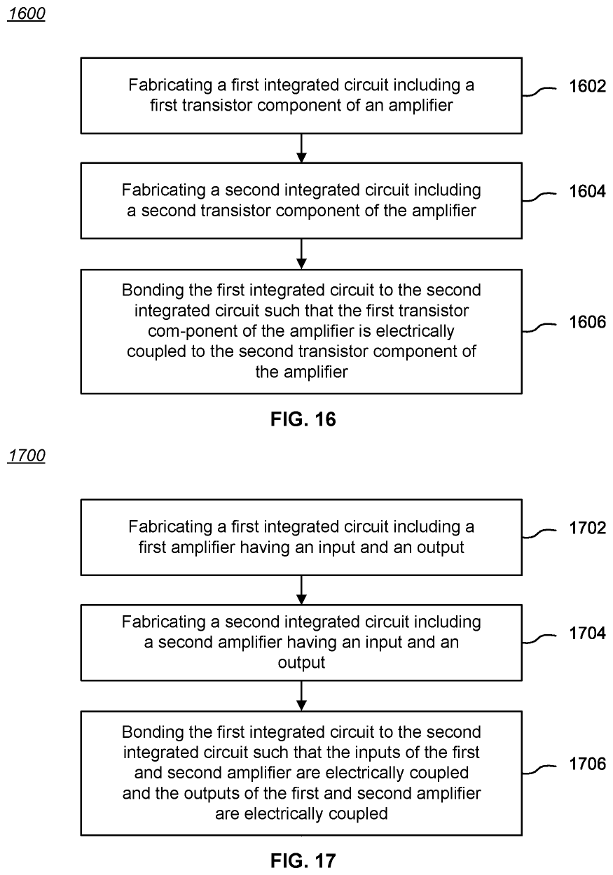

Another aspect of the invention includes methods for fabricating 3D ICs. For example, FIG. 16 is a process flow chart 1600 showing a first method for fabricating a 3-dimensional integrated circuit. The method includes: fabricating a first integrated circuit including a first transistor component of an amplifier (Block 1602); fabricating a second integrated circuit including a second transistor component of the amplifier (Block 1602); and bonding the first integrated circuit to the second integrated circuit such that the first transistor component of the amplifier is electrically coupled to the second transistor component of the amplifier (Block 1606).

As another example, FIG. 17 is a process flow chart 1700 showing a second method for fabricating a 3-dimensional integrated circuit. The method includes: fabricating a first integrated circuit including a first amplifier having an input and an output (Block 1702); fabricating a second integrated circuit including a second amplifier having an input and an output (Block 1702); and bonding the first integrated circuit to the second integrated circuit such that the inputs of the first and second amplifier are electrically coupled and the outputs of the first and second amplifier are electrically coupled (Block 1706).

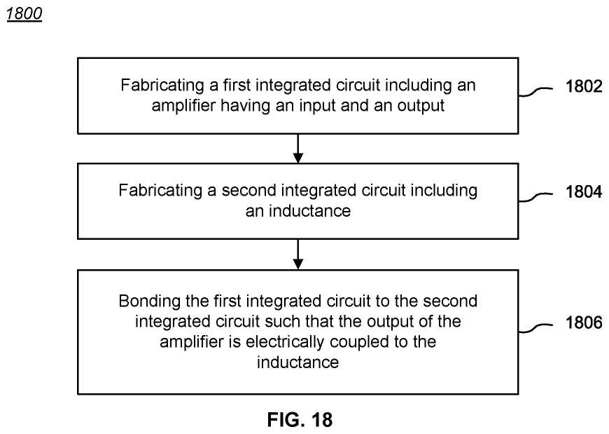

As yet another example, FIG. 18 is a process flow chart 1800 showing a third method for fabricating a 3-dimensional integrated circuit. The method includes: fabricating a first integrated circuit including an amplifier having an input and an output (Block 1802); fabricating a second integrated circuit including an inductance (Block 1802); and bonding the first integrated circuit to the second integrated circuit such that the output of the amplifier is electrically coupled to the inductance (Block 1806).

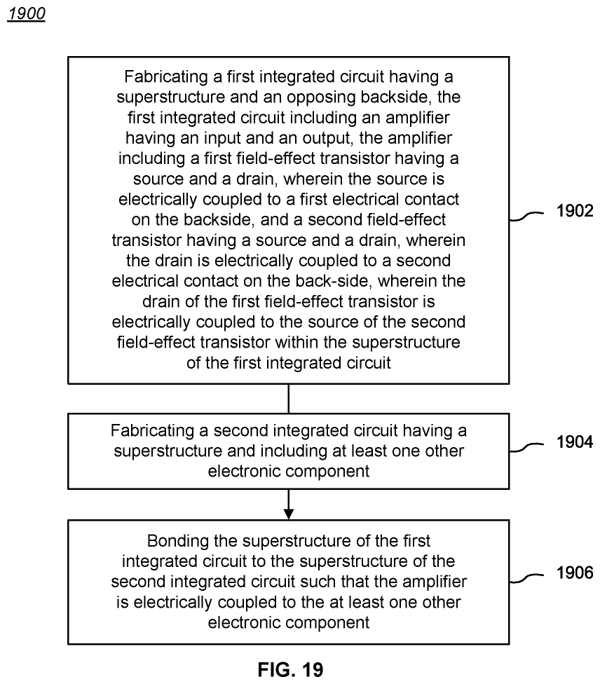

As still another example, FIG. 19 is a process flow chart 1900 showing a fourth method for fabricating a 3-dimensional integrated circuit. The method includes: fabricating a first integrated circuit having a superstructure and an opposing backside, the first integrated circuit including an amplifier having an input and an output, the amplifier including a first field-effect transistor having a source and a drain, wherein the source is electrically coupled to a first electrical contact on the backside, and a second field-effect transistor having a source and a drain, wherein the drain is electrically coupled to a second electrical contact on the backside, wherein the drain of the first field-effect transistor is electrically coupled to the source of the second field-effect transistor within the superstructure of the first integrated circuit (Block 1902); fabricating a second integrated circuit having a superstructure and including at least one other electronic component (Block 1902); and bonding the superstructure of the first integrated circuit to the superstructure of the second integrated circuit such that the amplifier is electrically coupled to the at least one other electronic component (Block 1906).

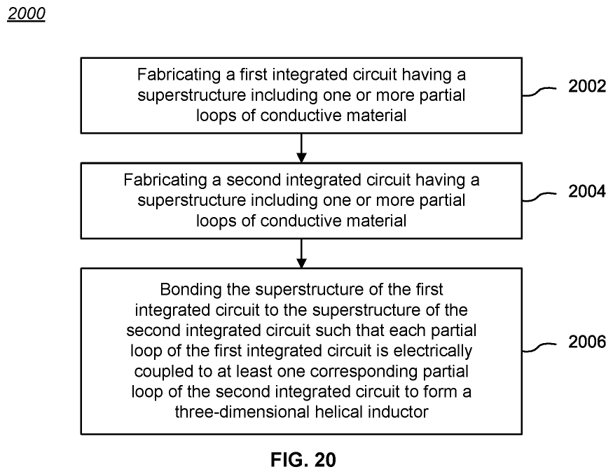

As a final example, FIG. 20 is a process flow chart 2000 showing a fifth method for fabricating a 3-dimensional integrated circuit. The method includes: fabricating a first integrated circuit having a superstructure including one or more partial loops of conductive material (Block 2002); fabricating a second integrated circuit having a superstructure including one or more partial loops of conductive material (Block 2002); and bonding the superstructure of the first integrated circuit to the superstructure of the second integrated circuit such that each partial loop of the first integrated circuit is electrically coupled to at least one corresponding partial loop of the second integrated circuit to form a three-dimensional helical inductor (Block 2006).

Additional aspects of the above method may include one or more of the following: wherein the amplifier is a low-noise amplifier; wherein the first and second amplifiers are low-noise amplifiers; wherein the first transistor component is a common source field-effect transistor; wherein the second transistor component is a common gate field-effect transistor; further including offsetting the first integrated circuit laterally from the second integrated circuit; further including vertically aligning the first integrated circuit with the second integrated circuit along a Z axis of the 3-dimensional integrated circuit; further including fabricating at least one of the first integrated circuit or the second integrated circuit using one of SOI or trap rich Si technology; further including fabricating at least one of the first integrated circuit or the second integrated circuit using one of bulk Si or high-resistivity bulk Si technology; further including fabricating the first integrated circuit using one of SOI or trap rich Si technology, and fabricating the second integrated circuit using one of bulk Si or high-resistivity bulk Si technology; wherein the inductance includes a planar coil of conductive material; wherein the inductance includes a parasitic inductance of conductive signal path routing coupled to the output of the amplifier; wherein the 3-dimensional integrated circuit is configurable to amplify an input signal through only the first amplifier, or only the second amplifier, or both the first and second amplifiers; further including positioning at least one circuit element with respect to at least one of the first field-effect transistor or the second field-effect transistor so as to be able to alter a threshold voltage VT of the first field-effect transistor or the second field-effect transistor when a selected voltage is applied to the at least one circuit element; wherein the at least one circuit element is a conductive aligned supplemental gate formed adjacent to a body of the first field-effect transistor or the second field-effect transistor; and/or wherein the at least one circuit element is a conductive via connected to or near to a body of the first field-effect transistor or the second field-effect transistor.

While the focus of the above examples has been LNAs, the methods and structures of this disclosure may be extended to other types of amplifiers, including power amplifiers.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar junction transistors (BJTs), BiCMOS, LDMOS, BCD, GaAs HBT, InP HBT, GaN HEMT, GaAs pHEMT, InP HEMT and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1.-69. (canceled)

70. A 3-dimensional integrated circuit including:
a first integrated circuit having a superstructure and an opposing backside, the first integrated circuit including an amplifier having an input and an output, the amplifier including:
a first field-effect transistor having a source and a drain, wherein the source is electrically coupled to a first electrical contact on the backside; and
a second field-effect transistor having a source and a drain, wherein the drain is electrically coupled to a second electrical contact on the backside;
wherein the drain of the first field-effect transistor is electrically coupled to the source of the second field-effect transistor within the superstructure of the first integrated circuit; and
a second integrated circuit having a superstructure and including at least one other electronic component;
wherein the superstructure of the first integrated circuit is bonded to the superstructure of the second integrated circuit such that the amplifier is electrically coupled to the at least one other electronic component.

71. The circuit of claim 70, wherein the amplifier is a low-noise amplifier.

72. The circuit of claim 70, wherein at least one of the first integrated circuit or the second integrated circuit is fabricated using one of SOI or trap rich Si technology.

73. The circuit of claim 70, wherein at least one of the first integrated circuit or the second integrated circuit is fabricated using one of bulk Si or high-resistivity bulk Si technology.

74. The circuit of claim 70, wherein the first integrated circuit is fabricated using one of SOI or trap rich Si technology, and the second integrated circuit is fabricated using one of bulk Si or high-resistivity bulk Si technology.

75. The circuit of claim 70, further including at least one circuit element positioned with respect to at least one of the first field-effect transistor or the second field-effect transistor so as to be able to alter a threshold voltage V_{T} of the first field-effect transistor or the second field-effect transistor when a selected voltage is applied to the at least one circuit element.

76. The circuit of claim 75, wherein the at least one circuit element is a conductive aligned supplemental gate formed adjacent to a body of the first field-effect transistor or the second field-effect transistor.

77. The circuit of claim 75, wherein the at least one circuit element is a conductive via connected to or near to a body of the first field-effect transistor or the second field-effect transistor.

78. The circuit of claim 70, wherein:
(a) the superstructure of the first integrated circuit includes one or more partial loops of conductive material; and
(b) the superstructure of the second integrated circuit includes one or more partial loops of conductive material;
wherein the superstructure of the first integrated circuit is bonded to the superstructure of the second integrated circuit such that each partial loop of the first integrated circuit is electrically coupled to at least one corresponding partial loop of the second integrated circuit to form a three-dimensional helical inductor.

79. The circuit of claim 78, wherein at least one of the first integrated circuit or the second integrated circuit is fabricated using one of SOI or trap rich Si technology.

80. The circuit of claim 78, wherein at least one of the first integrated circuit or the second integrated circuit is fabricated using one of bulk Si or high-resistivity bulk Si technology.

81. The circuit of claim 78, wherein the first integrated circuit is fabricated using one of SOI or trap rich Si technology, and the second integrated circuit is fabricated using one of bulk Si or high-resistivity bulk Si technology.

82. A method of fabricating a 3-dimensional integrated circuit including:
a. fabricating a first integrated circuit having a superstructure and an opposing backside, the first integrated circuit including an amplifier having an input and an output, the amplifier including:
i. a first field-effect transistor having a source and a drain, wherein the source is electrically coupled to a first electrical contact on the backside; and
ii. a second field-effect transistor having a source and a drain, wherein the drain is electrically coupled to a second electrical contact on the backside;
wherein the drain of the first field-effect transistor is electrically coupled to the source of the second field-effect transistor within the superstructure of the first integrated circuit;
b. fabricating a second integrated circuit having a superstructure and including at least one other electronic component; and
c. bonding the superstructure of the first integrated circuit to the superstructure of the second integrated circuit such that the amplifier is electrically coupled to the at least one other electronic component.

83. The method of claim 82, wherein the amplifier is a low-noise amplifier.

84. The method of claim 82, further including fabricating at least one of the first integrated circuit or the second integrated circuit using one of SOI or trap rich Si technology.

85. The method of claim 82, further including fabricating at least one of the first integrated circuit or the second integrated circuit using one of bulk Si or high-resistivity bulk Si technology.

86. The method of claim 82, further including fabricating the first integrated circuit using one of SOI or trap rich Si technology, and fabricating the second integrated circuit using one of bulk Si or high-resistivity bulk Si technology.

87. The method of claim 82, further including positioning at least one circuit element with respect to at least one of the first field-effect transistor or the second field-effect transistor so as to be able to alter a threshold voltage V_{T} of the first field-effect transistor or the second field-effect transistor when a selected voltage is applied to the at least one circuit element.

88. The method of claim 87, wherein the at least one circuit element is a conductive aligned supplemental gate formed adjacent to a body of the first field-effect transistor or the second field-effect transistor.

89. The method of claim 88, wherein the at least one circuit element is a conductive via connected to or near to a body of the first field-effect transistor or the second field-effect transistor.
